(19) United States
(12) Patent Application Publication
(10) Pub. No.: US 2009/0008732 A1
(43) Pub. Date: Jan. 8, 2009

(54) SEMICONDUCTOR PACKAGE

(75) Inventor: Kazuaki Kojima, Kamiina-gun (JP)

Correspondence Address: SCULLY SCOTT MURPHY & PRESSER, PC, 400 GARDEN CITY PLAZA, SUITE 300, GARDEN CITY, NY, 11530, US

(73) Assignee: OLYMPUS CORPORATION, Tokyo (JP)

(21) Appl. No.: 12/167,766

(22) Filed: Jul. 3, 2008

(30) Foreign Application Priority Data
Jul. 5, 2007 (JP) 2007-177718

(51) Int. Cl. H01L 31/0203; H01L 23/48

(52) U.S. Cl. 257/434; 257/621; 257/E23.01; 257/E31.11

(57) ABSTRACT

A chip-size semiconductor package can respond also to a semiconductor device in which an electrode pad pitch is narrow. A semiconductor package comprises a semiconductor substrate which has a first principal plane and a second principal plane, a circuit element formed on the first principal plane, two or more electrode pads connected to the circuit element provided on the first principal plane, two or more external connection terminals provided on the second principal plane, one or more through holes which reach at the second principal plane from the first principal plane, and two or more through wirings which connect the two or more electrode pads and the two or more external connection terminals through the one or more through holes respectively.

### CROSS REFERENCE TO RELATED APPLICATION

This application claims the benefit of Japanese Application No. 2007-177718 filed in Japan on Jul. 5, 2007, the contents of which are incorporated herein this by reference.

### BACKGROUND OF THE INVENTION

1. Field of the Invention

The present invention relates to a chip-size semiconductor package equipped with a semiconductor integrated circuit.

2. Description of the Related Art

In recent years, demands for cellular phones, portable audio players, etc. have increased, and miniaturization of various components mounted thereon has been progressing. In connection with it, further miniaturization is demanded also in their housing and internal circuit boards. Such a request for miniaturization is similarly requested naturally to a semiconductor device which is one of mounting components which configure a circuit board. In order to accept those demands, for example, development of electronic devices represented by a solid-state image pickup device, or devices produced using Micro Electro Mechanical Systems techniques represented by an acceleration sensor etc. (hereinafter, MEMS devices) has been progressing.

Then, in order to realize cost reduction of these electronic devices or MEMS devices (hereinafter, “devices”), development of chip size packages (hereinafter, they are called “CSPs”), and in particular, wafer level chip size packages (they are called “WL-CSPs”) which are divided into pieces by dicing or the like after bonding a board, which becomes caps, and a semiconductor substrate in which devices are formed.

As described in Japanese Patent No. 3313547, a WL-CSP has generally a resin and rewiring on an element surface of a silicon wafer, and external connection terminals which are post metals, solder balls, or the like for soldering connection are arranged in arbitrary locations on the element surface of the silicon wafer.

In addition, in International Publication No. WO 2005/022631, a semiconductor package which is made to be a WL-CSP by forming through holes in a substrate in which semiconductor devices which are solid-state image pickup devices are formed, connecting pad electrodes in an device face side and external connection terminals formed in a backside through the above-mentioned through holes, and dividing the above-mentioned device substrate into each package element is disclosed.

FIGS. 1 to 3 are diagrams for describing configuration of a conventional semiconductor package 100 described in the above-mentioned patent document 2. FIG. 1 is a top view of the conventional semiconductor package 100. FIG. 2 is a sectional view of the semiconductor package 100 taken along line II-II in FIG. 1. FIG. 3 is a bottom perspective view of the conventional semiconductor package 100.

The semiconductor package 100 comprises a supporting substrate 104 and a semiconductor substrate 101 which are bonded through an adhesive layer 105, as shown in FIGS. 1, 2, and 3. A circuit element 103 is formed on one side of the semiconductor substrate 101, and two or more electrode pads 106 are arranged around the circuit element 103. Respective through holes 112 are provided corresponding to respective electrode pads 106 which output and input signals with the circuit element 103. Each through hole 112 has a tapered shape. Each electrode pad 106 and a metallic post 111 for connection with the external are connected by an external wiring 109 passing through each through hole 112.

### SUMMARY OF THE INVENTION

A semiconductor package of the present invention includes a semiconductor substrate which has a first principal plane and a second principal plane, a circuit element formed on the above-mentioned first principal plane, two or more electrode pads connected to the above-mentioned circuit element provided on the above-mentioned first principal plane, two or more external connection terminals provided on the above-mentioned second principal plane, one or more through holes which reach at the above-mentioned second principal plane from the above-mentioned first principal plane, and two or more wirings which connect above-mentioned two or more electrode pads and above-mentioned two or more external connection terminals through the above-mentioned one or more through holes respectively.

### BRIEF DESCRIPTION OF THE DRAWINGS

FIG. 1 is a top view of a conventional semiconductor package;

FIG. 2 is a sectional view of the conventional semiconductor package;

FIG. 3 is a bottom perspective view of the conventional semiconductor package;

FIG. 4 is a sectional view of a semiconductor package according to an embodiment of the present invention; and

FIG. 5 is a bottom view of the semiconductor package according to the embodiment of the present invention.

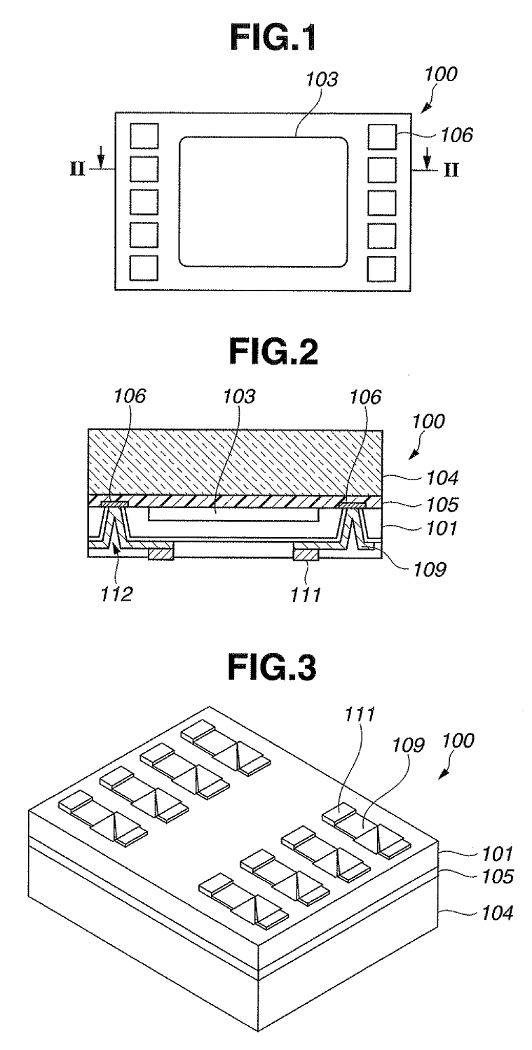

### DETAILED DESCRIPTION OF THE PREFERRED EMBODIMENTS

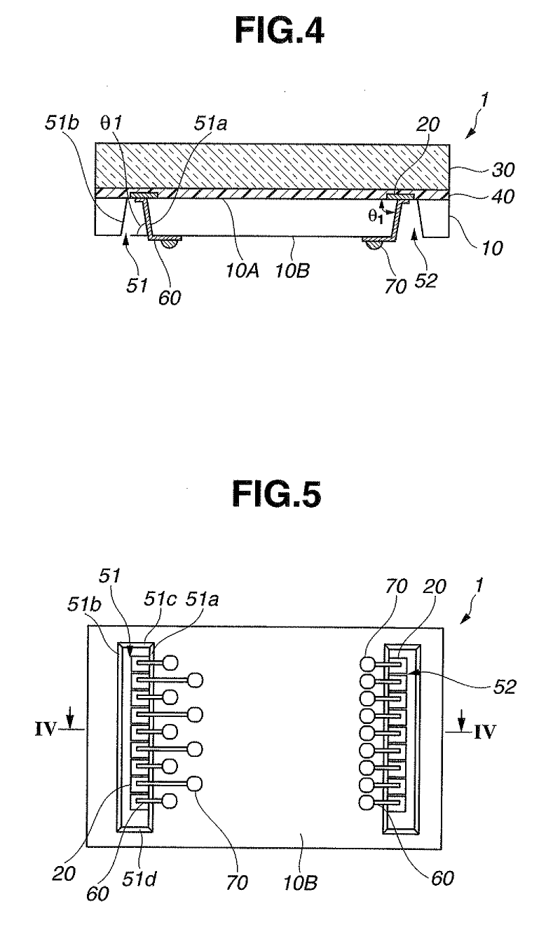

Hereafter, an embodiment of the present invention will be described with reference to the drawings. FIG. 4 is a sectional view of a semiconductor package 1 according to the embodiment of the present invention which is taken along line IV-IV in FIG. 5. FIG. 5 is a bottom view of the semiconductor package 1 according to the embodiment of the present invention.

The semiconductor package 1 shown in FIGS. 4 and 5 is a WL-CSP which is obtained by performing a dicing process into individual chips.

A semiconductor substrate 10 is a flat plate which has a first principal plane 10A and a second principal plane 10B which are parallel mutually. Then, a circuit element (not illustrated) is formed on the first principal plane 10A. Two or more electrode pads 20 which is electrically connected to the circuit element are provided in a region, in which the circuit element is not formed, on the first principal plane 10A of the semiconductor substrate 10.

Then, a supporting substrate 30 is arranged on the first principal plane 10A of the semiconductor substrate 10. The supporting substrate 30 is bonded with the semiconductor substrate 10 with an adhesive 40.

In the semiconductor substrate 10, two through holes 51 and 52 are formed in the vicinity of a part, in which the electrode pads 20 are provided, from the second principal plane 10B to the first principal plane 10A. Although through holes are the two through holes 51 and 52 in the embodiment, the number of the through holes in the semiconductor substrate 10 may be one or more. Hereafter, the through hole 51 will be described between the two through holes 51 and 52.

In the embodiment, a sectional shape of each through hole at the time of cutting it with a plane parallel to the first principal plane 10A or second principal plane 10B is a rectangle, and each through hole has four wall surfaces. That is, as shown in FIGS. 4 and 5, the through hole 51 has four wall surfaces 51a, 51b, 51c, and 51d.

The each through hole 51 is formed so as to straddle two or more electrode pads 20. In other words, each through wiring is formed so as to include at least portions of respective two or more electrode pads 20. In addition, after the electrode pads 20 are formed on the first principal plane 10A, the through hole 51 is formed from a side of the second principal plane 10B. For this reason, portions of the electrode pads 20 observed from the side of the second principal plane 10B through the through hole 51 after through hole formation are backsides at the time of forming the electrode pads 20.

Then, it is preferable that the wall surfaces of each through hole 51 is not parallel to a plane orthogonal to the second principal plane 10B, but have taper sections at specified angles. In the embodiment, as shown in FIG. 4, each inside wall in each through hole has such a tapered shape that a sectional area of the through hole 51 becomes small toward the first principal plane 10A from the second principal plane 10B of the semiconductor substrate 10. That is, an angle θ1 which the second principal plane 10B and the wall surface 51a of the through hole 51 make is an acute angle which is less than 90°.

Since the wall surfaces of each through hole 51 have such tapered shapes, when forming a through wiring 60 mentioned later by a sputtering method etc. and performing patterning on the wall surface of each through hole 51, it is easy to form the through wiring 60. In addition, since cross sections of transitions to the first principal plane 10A and the second principal plane 10B from on the tapered faces of the through wirings 60 become gentle slopes, breaking of wires of the through wirings 60 in the transitions do not take place easily.

In addition, it is not necessary that the wall surfaces of all the through holes 51 have the tapered shapes with the principal planes of the semiconductor substrate 10. At least a wall surface of the through hole 51 on which the through wiring 60 is formed may have a tapered shape with the first principal plane 10A and second principal plane 10B of the semiconductor substrate 10. For example, in a through hole 51 in the left-hand side in FIG. 5, the wall surface 51a of the through hole 51 may have a tapered shape with a first principal plane 10A, and it is not necessary that wall surfaces 51b, 51c, and 51d of the through hole 51 have tapered shapes with the first principal plane 10A.

It is preferable that a tapered angle θ1 which a wall surface of the through hole 51 and the first principal plane 10A of the semiconductor substrate 10 forms is about 45° to 75°. It is because, when the angle is less than the above-mentioned range, the area necessary for through hole formation becomes large for a restriction to arise in a design, and when it exceeds the above-mentioned range, technical difficulty becomes high in through wiring formation by photolithography and the like which are post processes to decrease a product yield.

The each through wiring 60 is electrically connected to a corresponding electrode pad 20 on the first principal plane 10A of the semiconductor substrate 10, and is electrically connected to a corresponding external connection terminal 70 on the second principal plane 10B of the semiconductor substrate 10 through the wall surface of the through hole 51. Two or more through wirings 60 are connected to two or more electrode pads 20 respectively, and they are electrically insulated mutually. Namely, the semiconductor package 1 of the embodiment has the two or more through wirings 60 which electrically connect the two or more electrode pads 20 and the two or more external connection terminals 70 through one through hole 51 formed in the semiconductor substrate 10 and are electrically insulated mutually.

In the embodiment, for example, in the through hole 51 in the left-hand side in FIG. 5, a through wiring 60 is formed only on one wall surface 51a among four wall surfaces 51a, 51b, 51c, and 51d. However, it is also good to form through wirings 60 using two or more wall surfaces. It becomes possible to arrange much more through wirings 60 in the semiconductor package 1 by forming the through wirings 60 using many wall surfaces.

In addition, as the circuit element formed on the first principal plane 10A of the semiconductor substrate 10, a semiconductor device which comprises a circuit element including a solid-state image pickup device, such as a CCD (Charge Coupled Device), a CMOS (Complementary Metal-Oxide Semiconductor), or the like, that is, a photo sensor, a signal processing circuit, and the like is cited as an example.

In addition, it is preferable as the supporting substrate 30 to select a member whose coefficient of thermal expansion at junctioning temperature with the semiconductor substrate 10 is nearly equal to that of the semiconductor substrate 10. Specifically as a material which has optical transparency, Pyrex (registered trademark) glass, a glass substrate generally used for a liquid crystal substrate, or the like is used preferably. In addition, when a circuit element is not a solid-state image pickup device or the like for which an optical characteristic is demanded, it is not necessary that the supporting substrate 30 is selected from materials which have optical transparency.

In addition, when the semiconductor substrate 10 and the supporting substrate 30 are junctioned by thermocompression bonding, it is good to use a polyimide resin, an epoxy resin, a BCB resin, or the like as an adhesive forming the adhesive layer 40.

In addition, as shown in the right-hand side in FIG. 5, it is not necessary to arrange the external connection terminals 70 on a straight line on the second principal plane 10B of a semiconductor substrate, but, as shown in the left-hand side in FIG. 5, it is also good to arrange them alternately, that is, in a so-called staggered shape. This can prevent a short circuit between wirings when a pitch gap between the external connection terminals 70 each of which has a line width wider than that of each of the through wirings 60 is narrow.

Hereafter, a production method of the semiconductor package 1 according to the embodiment will be described simply.

(1) Prepare the semiconductor substrate 10 in which a semiconductor circuit element containing a photo sensor and the like is formed on the first principal plane 10A, and the supporting substrate 30.

(2) Junction the first principal plane 10A of the semiconductor substrate 10 and supporting substrate 30 by thermocompression bonding or the like through the adhesive layer 40.

(3) Polish the semiconductor substrate 10 from a side of the second principal plane 10B of the semiconductor substrate 10 to perform thinning, if needed. In the polishing work, a polishing method using a standard back grinder (BG), chemical mechanical polishing equipment (CMP), or the like is used. Furthermore, the polishing method is not limited to the method of using a BG or CMP, but so long as it is a method of performing thinning of the second principal plane 10B of the semiconductor substrate 10 uniformly in a range of not having a trouble in a post process, any methods can be applied. As the polishing method, a wet etching method or a dry etching method, such as reactive ion etching (RIE), or chemical dry etching (CDE), for example may be used.

(4) Subsequently, as a post process, perform patterning of a thin film used as a mask in a through hole formation etching process of the semiconductor substrate 10 in the second principal plane 10B of the semiconductor substrate 10 which is thinned. As a mask thin film, it is desirable to use, for example, a low-temperature PCVD oxide layer or a low-temperature PCVD nitride film which can be formed as a film at about 200° C., or a spin coating film, such as a spin-on glass film or a fluororesin.

(5) Form the through hole 51 ranging from the side of the second principal plane 10B to the first principal plane 10A of the semiconductor substrate 10 up to positions in which at least parts of backsides of the electrode pads 20 expose, by etching the semiconductor substrate 10 with using the mask thin film as a mask.

In order to make a through wall of the through hole 51 tapered, it is possible to use anisotropic etching preferably. Although a wet etching method using a tetramethylammonium hydroxide (TMAH) aqueous solution, a potassium hydroxide (KOH) aqueous solution, or the like is desirable as the anisotropic etching, it is also possible to use a dry etching method, such as reactive ion etching (RIE) or chemical dry etching (CDE).

For example, when a silicon (100) plane is used as the semiconductor substrate 10, since it becomes anisotropic etching that an etch rate of a (111) plane is smaller than that of the (100) plane, wall surfaces of the through hole 51 become (111) planes, and an angle θ1 with the (100) plane becomes 54.74° for taper sections to be formed. It is particularly preferable since the taper angle θ1 obtained by this method is repeatedly feasible and is advantageous also for through wiring production.

(6) Next, form an insulating film on the second principal plane 10B of the semiconductor substrate 10, backsides of the electrode pads 20, the walls of the through hole 51, and the like. In addition, the insulating film is not shown in FIGS. 4 and 5. As the electrical insulation film, it is possible to use, for example, a low-temperature PCVD oxide layer or a low-temperature PCVD nitride film which can be formed as a film at about 200° C., or a spin coating film, such as a spin-on glass film or a fluororesin.

(7) Remove selectively the electrical insulation film formed on the backsides of the electrode pads 20. Here, a semiconductor photolithography process and an etching process using a standard resist are used.

(8) Form the through wirings 60 which are made of metal thin films inside the through hole 51 and on the second principal plane 10B of the semiconductor substrate 10 with making at least parts of backsides of the electrode pads 20 base ends. In addition, each of the external connection terminals 70 of these through wirings 60 electrically connected to each of the through wirings 60 is formed on the second principal plane 10B of the semiconductor substrate 10. It is also good to simultaneously form the through wirings 60 and external connection terminals 70 by forming the metal thin film by a general sputtering method, an evaporation method, or the like, and thereafter, patterning the metal thin film into desired shapes by the semiconductor photolithography process and etching process.

In addition, it is good in consideration of reliability enhancement to perform plating surface treatment with gold, nickel, or the like on surfaces of the patterned through wirings 60 and external connection terminals 70, if needed. Although aluminum is usually used as a material of the through wirings 60 and external connection terminals 70, so long as it is a material which is the same as a constituent material of the electrode pads 20, or has chemical affinity, metallic materials such as copper, nickel, and gold may be also used.

(9) In order to interrupt the through wirings 60 and external connection terminals 70 from the open air, and in particular, humidity, form an overcoat on these if needed. In addition, the overcoat is not shown in FIGS. 4 and 5. The overcoat is made of a material which has electric insulation and has a sufficient heat resistance and corrosion resistance. As the overcoat, a silicon nitride film, a silicon oxide film, and the like which are formed using a low-temperature CVD method are desirable. For example, the external connection terminals 70 are exposed by forming a thin film which is made of a silicon nitride film or a silicon oxide film, which turns into the overcoat, by a plasma CVD method etc., and thereafter, removing parts of the formed thin films selectively by a semiconductor photolithography process and an etching process.

As described above, according to the semiconductor package 1 according to the embodiment, two or more through wirings 60 electrically insulated can be formed on one through hole 51. In particular, in the semiconductor package 1 according to the embodiment, the through hole 51 has a taper section and the through wirings 60 are formed along the tapered face of the taper section. For this reason, it is possible to respond to the semiconductor package 1 in narrow pitch pad arrangement up to the limit on line/space operation of the through wirings 60 formed on the wall surface of the through hole 51. For this reason, it is possible to respond to miniaturization of the semiconductor package 1, or multiple pin arrangement.

In addition, as for the through hole 51, it is preferable that a sectional shape parallel to the principal plane of the semiconductor substrate is a rectangle, and in particular, a rectangle one pair of whose sides is long as shown in FIG. 5 is preferable. It is because it is possible to arrange a large number of through wirings 60 on one of the pair of long side sections.

The number of the through wirings 60 arranged in one through hole 51 may be just two or more, and in particular, in order to obtain an advantageous effect of the embodiment greatly, it is preferable to arrange the required through wirings 60 in the smallest number of through holes 51. Although an upper limit of the number of the through wirings 60 is determined by the limit on the line/space operation as mentioned above, and a perimeter of the through hole 51, so long as it is possible to form each through wiring 60 with a line thinner than a width of each electrode pad 20, a restriction does not arise in practice.

As described above, the semiconductor package according to the embodiment mentioned above can respond also to a semiconductor device with narrow electrode pad pitches in comparison with a conventional semiconductor package.

Having described the preferred embodiments of the invention referring to the accompanying drawings, it should be understood that the present invention is not limited to those precise embodiments and various changes and modifications thereof could be made by one skilled in the art without departing from the spirit or scope of the invention as defined in the appended claims.

What is claimed is:

1. A semiconductor package, comprising:
a semiconductor substrate which has a first principal plane and a second principal plane;
a circuit element formed on the first principal plane;
two or more electrode pads connected to the circuit element provided on the first principal plane;
two or more external connection terminals provided on the second principal plane;
one or more through holes which reach at the second principal plane from the first principal plane; and
two or more wirings which connect the two or more electrode pads and the two or more external connection terminals through the one or more through holes respectively.

2. The semiconductor package according to claim 1, wherein an inside wall surface of the through hole has a taper section which has a predetermined angle with respect to the first principal plane.

3. The semiconductor package according to claim 1, wherein an inside wall surface of the through hole has a taper section which has an angle of 45 to 75° with respect to the first principal plane.

4. The semiconductor package according to claim 1, wherein an inside wall surface of the through hole has a taper section which has a predetermined angle with respect to the first principal plane and is formed by anisotropic etching.

5. The semiconductor package according to claim 1, wherein the semiconductor substrate is a silicon substrate; and
wherein one or more inside wall surfaces of the through hole have taper sections each of which has an angle of 55° to the first principal plane.

6. The semiconductor package according to claim 1, wherein a shape of a cross section of the through hole which is parallel to the second principal plane is a rectangle.

7. The semiconductor package according to claim 1, wherein a second principal plane side of each of the electrode pads is connected to each of the wirings.

8. The semiconductor package according to claim 1, further comprising:
a supporting substrate arranged on the first principal plane.

9. A semiconductor package, comprising:
a silicon substrate which has a first principal plane and a second principal plane which have a (100) plane orientation;
a solid-state image pickup device formed on the first principal plane;
a supporting substrate which is arranged on the first principal plane and has optical transparency;
two or more electrode pads connected to the solid-state image pickup device provided on the first principal plane;
two or more external connection terminals provided on the second principal plane;
one or more through holes each shape of whose cross sections parallel to the second principal plane is a rectangle, in which at least one inside wall surface has a taper section with an angle of 55° to the first principal plane, and which reach the second principal plane from the first principal plane; and
two or more wirings which connect the two or more electrode pads and the two or more external connection terminals through the one or more through holes respectively.

10. The semiconductor package according to claim 9, wherein a second principal plane side of each of the electrode pads is connected to each of the wirings.
